(19) United States
(12) Patent Application Publication
(10) Pub. No.: US 2026/0130137 A1
(43) Pub. Date: May 7, 2026

(54) METAL SILICIDE POST TREATMENT TO ENHANCE THERMAL STABILITY

(71) Applicant: Applied Materials, Inc., Santa Clara, CA (US)

(72) Inventors: Xi CEN, San Jose, CA (US); Ying-Bing JIANG, Woodland, CA (US); Yuxin WANG, San Jose, CA (US); Yao XU, Santa Clara, CA (US); Avgerinos V. GELATOS, Scotts Valley, CA (US); Joung Joo LEE, San Jose, CA (US); Kai WU, Palo Alto, CA (US); Cheng CHENG, Santa Clara, CA (US)

(21) Appl. No.: 18/935,240

(22) Filed: Nov. 1, 2024

(51) Int. Cl. H01L 21/321; H01L 21/285; H01L 21/3205

(52) U.S. Cl. CPC H10P 14/6316; H10P 14/414; H10P 14/43

(57) ABSTRACT

A method of forming and post-treating a metal silicide layer in a semiconductor structure includes performing a silicide deposition process, in which a metal silicide layer is deposited on a substrate, performing a chemical vapor deposition (CVD) soak process in which the metal silicide layer is exposed to a nitrogen (N)-containing liquid precursor, forming a metal silicide nitride layer, and performing a cap deposition process, in which a cap layer is deposited on the metal silicide nitride layer.

### BACKGROUND

### Field

Embodiments described herein generally relate to semiconductor device fabrication, and more particularly, to methods of forming and post-treating metal silicide.

### Description of the Related Art

The production of silicon integrated circuits has placed difficult demands on fabrication processes to increase the number of devices while decreasing the minimum feature sizes on a chip. These demands have extended to fabrication processes including depositing layers onto difficult topologies while maintaining device reliability. For example, in three dimensional (3D) dynamic random access memory (DRAM) devices or multi-gate metal-oxide-semiconductor field-effect transistors (MOSFETs), such as complementary metal-oxide semiconductor (CMOS) devices, metal silicide (e.g., molybdenum silicide (MoSiₓ), ruthenium silicide (RuₓSi_{y})) is often utilized to lower a contact resistivity. However, metal silicide (e.g., molybdenum silicide (MoSiₓ)) has been known to have thermal stability issues due to inter-diffusion of metal elements (e.g., molybdenum (Mo)) at interfaces between silicon (Si) and metal silicide (e.g., molybdenum silicide (MoSiₓ)) during a subsequent anneal process, causing device failure.

Therefore, there is a need for methods and systems that can form thermally stable metal silicide with reduced diffusion of metal elements (e.g., molybdenum (Mo)) out of a metal silicide.

### SUMMARY

Embodiments of the present disclosure provide a method of forming and post-treating a metal silicide layer in a semiconductor structure. The method includes performing a silicide deposition process, in which a metal silicide layer is deposited on a substrate, performing a chemical vapor deposition (CVD) soak process in which the metal silicide layer is exposed to a nitrogen (N)-containing liquid precursor, forming a metal silicide nitride layer, and performing a cap deposition process, in which a cap layer is deposited on the metal silicide nitride layer.

Embodiments of the present disclosure also provide a method of forming and post-treating a metal silicide layer in a semiconductor structure. The method includes performing a silicide deposition process, in which a metal silicide layer is deposited on a substrate, performing a chemical vapor deposition (CVD) soak process in which the metal silicide layer is exposed to a silicon-containing precursor, forming a thin silicon (Si) layer over the metal silicide layer; and performing a cap deposition process, in which a cap layer is deposited over the metal silicide layer.

Embodiments of the present disclosure further provide a method of forming and post-treating a metal silicide layer in a semiconductor structure. The method includes performing a silicide deposition process, in which a metal silicide layer is deposited on a substrate, performing an anneal process in which the metal silicide layer is crystalized, forming a crystalized metal silicide layer over the metal silicide layer, and performing a cap deposition process, in which a cap layer is deposited over the metal silicide layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of an exemplary substrate processing system according to one or more embodiments of the present disclosure.

FIG. 2 depicts a process flow diagram of a method of forming and post-treating a metal silicide layer in a semiconductor structure according to one or more embodiments of the present disclosure.

FIGS. 3A, 3B, 3C, 3D, 3E, 3F, 3G, 3H, and 3I are cross-sectional views of a portion of a semiconductor structure corresponding to various states of the method of FIG. 2.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide methods for forming and post-treating metal silicide (e.g., molybdenum silicide (MoSiₓ), ruthenium silicide (RuₓSi_{y})) that can be used to reduce a contact resistance in three dimensional (3D) dynamic random access memory (DRAM) devices or multi-gate metal-oxide-semiconductor field-effect transistors (MOSFETs). Three embodiments of post-treatment of metal silicide described below include (1) a chemical vapor deposition (CVD) soak in a nitrogen (N)-containing liquid precursor, (2) a CVD soak in a silicon-containing precursor, and (3) a thermal anneal, which all reduce diffusion of metal elements (e.g., molybdenm (Mo)) out of the metal silicide (e.g., molybdenum silicide (MoSiₓ)) during a subsequent anneal process that causes device failure.

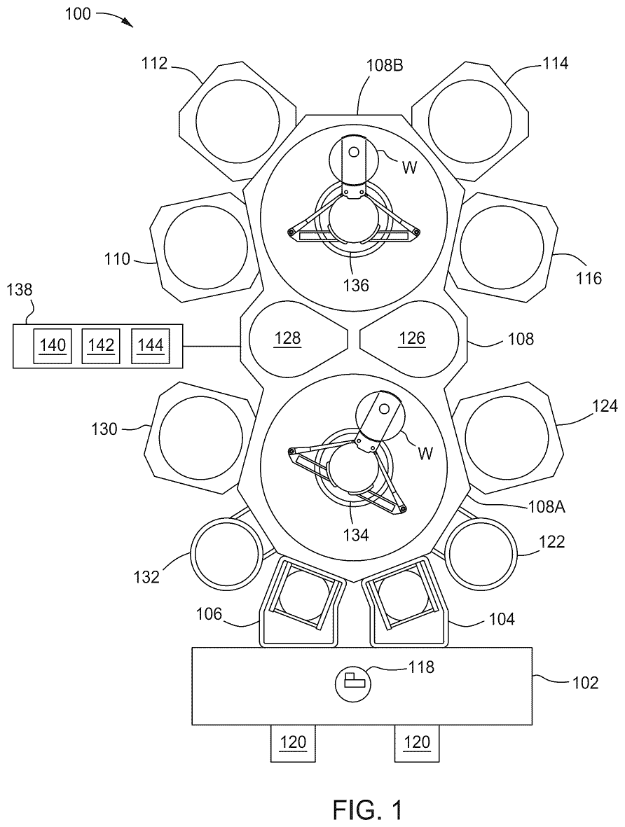

FIG. 1 is a schematic top view of an exemplary substrate processing system 100, according to one or more embodiments. The processing system 100 generally includes an equipment front-end module (EFEM) 102 for loading substrates into the processing system 100, a first load lock chamber 104 and a second load lock chamber 106 coupled to the EFEM 102, a transfer chamber 108 coupled to the first load lock chamber 104, and processing chambers 110, 112, 114, and 116 coupled to the transfer chamber 108. The EFEM 102 generally includes one or more robots 118 that are configured to transfer substrates from one or more front opening unified pods (FOUPs) 120 to at least one of the first load lock chamber 104 or the second load lock chamber 106. Proceeding counterclockwise around the transfer chamber 108 from a buffer portion 108A of the transfer chamber 108, the processing system 100 includes the first load lock chamber 104, the second load lock chamber 106, processing chambers 122, 124, pass-through chambers 126, 128, and processing chambers 130, 132. The buffer portion 108A of the transfer chamber 108 includes a first robot 134 that is configured to transfer substrates to each of the chambers 104, 106, 122, 124, 126, 128, 130, 132.

A back-end portion 108B of the transfer chamber 108 of the includes a second robot 136 that is configured to transfer substrates W to each of the pass-through chambers 126, 128 and the processing chambers 110, 112, 114, and 116 coupled to the back-end portion 108B of the processing system 100. In general, the processing chamber 122 can be a degas chamber, the processing chamber 132 is a pre-clean chamber, and the processing chambers 110, 112, 114, 116, 124, 130 can include at least one of an atomic layer deposition (ALD) chamber, a chemical vapor deposition (CVD) chamber, a physical vapor deposition (PVD) chamber, an etch chamber, a degas chamber, an anneal chamber, and other type of semiconductor substrate processing chamber.

The buffer portion 108A and the back-end portion 108B of the transfer chamber 108 and each chamber coupled to the transfer chamber 108 are maintained at a vacuum state. As used herein, the term “vacuum” may refer to pressures less than 760 Torr, and will typically be maintained at pressures near 10⁻⁵ Torr (i.e., ˜10⁻³ Pa). However, some high-vacuum systems may operate below near 10⁻⁷ Torr (i.e., ˜10⁻⁵ Pa). In certain embodiments, the vacuum is created using a rough pump (not shown) and/or a turbomolecular pump (not shown) coupled to the transfer chamber 108 and to each of the chambers. However, other types of vacuum pumps are also contemplated.

A system controller 138, such as a programmable computer, is coupled to the processing system 100 for controlling one or more of the components therein. In operation, the system controller 138 enables data acquisition and feedback from the respective components to coordinate processing in the processing system 100.

The system controller 138 includes a programmable central processing unit (CPU) 140, which is operable with a memory 142 (e.g., non-volatile memory) and support circuits 144. The support circuits 144 (e.g., cache, clock circuits, input/output subsystems, power supplies, etc., and combinations thereof) are conventionally coupled to the CPU 140 and coupled to the various components within the processing system 100.

In some embodiments, the CPU 140 is one of any form of general purpose computer processor used in an industrial setting, such as a programmable logic controller (PLC), for controlling various monitoring system component and sub-processors. The memory 142, coupled to the CPU 140, is non-transitory and is typically one or more of readily available memory such as random access memory (RAM), read only memory (ROM), floppy disk drive, hard disk, or any other form of digital storage, local or remote.

Herein, the memory 142 is in the form of a computer-readable storage media containing instructions (e.g., non-volatile memory), that when executed by the CPU 140, facilitates the operation of the processing system 100. The instructions in the memory 142 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored, and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

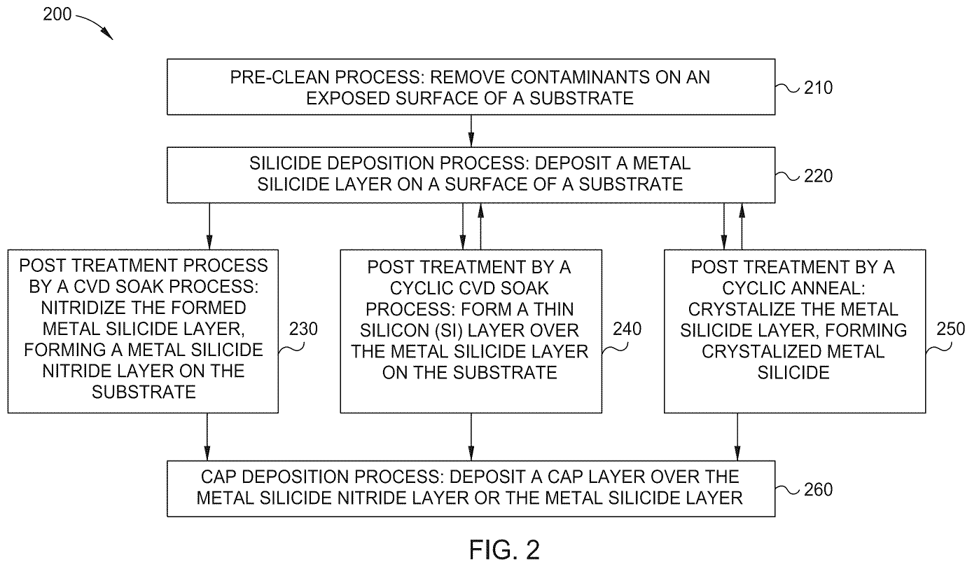

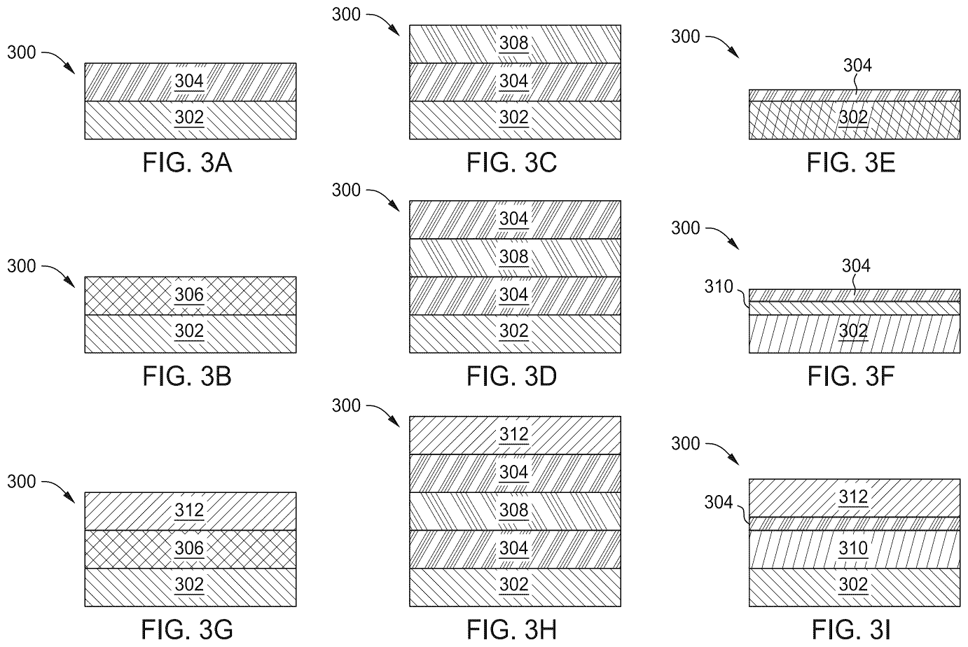

FIG. 2 depicts a process flow diagram of a method 200 of forming and post-treating a metal silicide layer in a semiconductor structure 300 according to some embodiments of the present disclosure. FIGS. 3A, 3B, 3C, 3D, 3E, 3F, and 3G, 3H, and 3I are cross-sectional views of a portion of the semiconductor structure 300 corresponding to various states of the method 200. It should be understood that FIGS. 3A, 3B, 3C, 3D, 3E, 3F, and 3G, 3H, and 3I illustrate only partial schematic views of the semiconductor structure 300, and the semiconductor structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

The method 200 begins with a pre-clean process in block 210. The pre-clean process may be performed in a processing chamber, such as the processing chamber 132 shown in FIG. 1.

The pre-clean process is configured to remove contaminants, such as carbon-containing contaminants (e.g., patterning residues), or oxide-containing contaminants (e.g., native oxide layers) formed on an exposed surface of a substrate 302.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The pre-clean process to remove oxide-containing contaminants may include an isotropic plasma etch process, such as a dry chemical etch process, using hydrofluoric acid (HF) and ammonia (NH₃), or a SiCoNi™ dry etch process, using a plasma formed from a gas including ammonia (NH₃), nitrogen trifluoride (NF₃). The dry etch process is selective for oxide layers, and thus does not readily etch silicon, germanium, or nitride layers regardless of whether the layers are amorphous, crystalline or polycrystalline. Selectivity of the dry etch process for oxide versus silicon or germanium is at least about 3:1, and usually 5:1 or better, sometimes 10:1. The dry etch process is also highly selective of oxide versus nitride. The selectivity of the dry etch process versus nitride is at least about 3:1, usually 5:1 or better, sometimes 10:1.

The pre-clean process to remove carbon-containing contaminants may include an anisotropic remote plasma assisted dry etch process, such as a reactive ion etching (RIE) process, using a plasma formed from a gas including hydrogen (H), argon (Ar), helium (He), or a combination thereof.

In block 220, a silicide deposition process is performed to deposit a metal silicide layer 304 on the pre-cleaned surface of the substrate 302, as shown in FIG. 3A. The metal silicide layer 304 may be formed of molybdenum silicide (MoSiₓ, x˜0.2-1), having a thickness of between about 30 Å and about 50 Å, for example, about 20 Å. The silicide deposition process may include atomic layer deposition (ALD) or pseudo ALD, performed in a processing chamber, such as the processing chamber 110, 112, 114, 116, 124, or 130 shown in FIG. 1.

In some embodiments, a deposition gas used in the silicide deposition process includes a metal source, such as a molybdenum (Mo)-containing halide precursor (e.g., molybdenum pentachloride (MoCl₅), molybdenum oxytetrachloride (MoOCl₄)) and hydrogen (H₂) precursor. The silicide deposition process may be performed at a temperature of between about 240° C. and about 450° C. and at a pressure of between 3 Torr and 300 Torr. During the silicide deposition process, hydrogen (H₂) gas may be supplied at a flow rate of between about 500 sccm and about 15000 sccm, for example.

In block 230, a post treatment process by a CVD soak process is performed to nitridize the formed metal silicide layer 304, forming a metal silicide nitride layer (e.g., molybdenum silicon nitride (MoSiₓN)) 306 on the substrate 302, as shown in FIG. 3B.

In the post treatment process by a CVD soak process, the metal silicide layer 304 is exposed to a nitrogen (N)-containing liquid precursor (e.g., ammonia (NH₃)) to nitridize the metal silicide layer 304. The CVD soak process may be performed in a processing chamber, such as the processing chamber 110, 112, 114, 116, 124, or 130 shown in FIG. 1, at a temperature of between about 300° C. to about 450° C., for a time period of between about 10 seconds about 30 seconds. The formed metal silicide nitride layer 306 is in a stable phase such that diffusion of metal elements (e.g., molybdenum (Mo)) out of the formed metal silicide nitride layer (e.g., molybdenum silicon nitride (MoSiₓN)) 306 during a subsequent anneal process may be prevented.

In block 240, alternative to block 230, a post treatment by a cyclic CVD soak process is performed to form a thin silicon (Si) layer 308 over the metal silicide layer 304, as shown in FIG. 3C. The thin silicon (Si) layer 308 may have a thickness of between about 5 Å and about 8 Å.

In the post treatment process by a cyclic CVD soak process, the metal silicide layer 304 is exposed to a silicon-containing precursor (e.g., silane (SiH₄), disilane (Si₂H₆), tetrasilane (Si₄H₁₀), or a combination thereof). After a cycle of the cyclic CVD soak process, the silicide deposition process in block 220 is performed to form another metal silicide layer 304 on the formed thin silicon (Si) layer 308, as shown in FIG. 3D. The cyclic CVD soak process may be performed in the same processing chamber, at the same temperature, as the silicide deposition process in block 220, for a time period of between about 10 seconds about 120 seconds, repeated for about 1 and about 3 cycles. The metal silicide layer 304 now has silicon (e.g., the substrate 302 and the thin silicon (Si) layer 308) on both side of the metal silicide layer 304 and diffusion of metal elements (e.g., molybdenum (Mo)) out of the metal silicide layer 304 in either side (e.g., the substrate 302 or the thin silicon (Si) layer 308) during a subsequent anneal process may be prevented.

In block 250, alternative to block 230 or block 240, a post treatment by a cyclic anneal is performed to crystalize the metal silicide layer 304, forming crystalized metal silicide layer (e.g., molybdenum disilicide (MoSi₂)) 310 over the metal silicide layer 304, as shown in FIG. 3E. Diffusion of metal elements (e.g., molybdenum (Mo)) out of the crystalized metal silicide layer (e.g., molybdenum disilicide (MoSi₂)) 310 during a subsequent anneal process may be prevented as vacancies in the molybdenum (Mo)) sublattice is significantly reduced.

The anneal process may include a thermal anneal process in reducing environment that includes argon (Ar) and/or nitrogen (N₂), performed in a rapid thermal processing (RTP) chamber, such as the processing chamber 110, 112, 114, 116, 124, or 130 shown in FIG. 1. After a cycle of the thermal anneal process, the silicide deposition process in block 220 is performed to form another metal silicide layer 304 on the formed crystalized metal silicide layer 310, as shown in FIG. 3F. The thermal anneal process may be performed for between about 5 second and about 60 seconds, at a temperature of between about 500° C. and about 600° C., and at a pressure of between about 5 Torr and 500 Torr, repeated for about 1 and about 3 cycles. The crystalized metal silicide layer 310 may be formed step by step to avoid mass transfer.

In block 260, a cap deposition process is performed, in which a cap layer 312 is deposited over the metal silicide nitride layer 306 or the metal silicide layer 304, as shown in FIGS. 3G, 3H, and 3I. The cap deposition process may include any appropriate deposition process, such as chemical vapor deposition (CVD), or physical vapor deposition (PVD), performed in a processing chamber, such as the processing chamber 110, 112, 114, 116, 124, or 130 shown in FIG. 1. The cap layer 312 may be formed of titanium nitride (TiN), combination of titanium nitride (TiN) and tungsten (W), tungsten (W), or molybdenum (Mo). The cap layer 312 may prevent oxidation of the metal silicide nitride layer 306 or the metal silicide layer 304 during a subsequent anneal process.

The embodiments described herein provide methods for forming and post-treating metal silicide to form a thermally stable metal silicide layer that can be used to reduce a contact resistance in 3D DRAM devices or multi-gate MOSFETs. Three embodiments of post-treatment of metal silicide described below include (1) a CVD soak in a nitrogen (N)-containing liquid precursor, (2) a CVD soak in a silicon-containing precursor, and (3) a thermal anneal, which all reduce diffusion of metal elements (e.g., molybdenm (Mo)) out of the metal silicide (e.g., molybdenum silicide (MoSiₓ)).

While the foregoing is directed to embodiments of the present disclosure, other and further embodiments of the disclosure may be devised without departing from the basic scope thereof, and the scope thereof is determined by the claims that follow.

1. A method of forming and post-treating a metal silicide layer in a semiconductor structure, comprising:
performing a silicide deposition process, in which a metal silicide layer is deposited on a substrate;
performing a chemical vapor deposition (CVD) soak process in which the metal silicide layer is exposed to a nitrogen (N)-containing liquid precursor, forming a metal silicide nitride layer; and
performing a cap deposition process, in which a cap layer is deposited on the metal silicide nitride layer.

2. The method of claim 1, wherein the metal silicide layer comprises molybdenum silicide.

3. The method of claim 1, wherein the metal silicide layer has a thickness of between 30 Å and 50 Å.

4. The method of claim 1, wherein the silicide deposition process comprises atomic layer deposition (ALD) or pseudo ALD using a deposition gas including a metal source.

5. The method of claim 4, wherein the silicide deposition process is performed at a temperature of between 240° C. and about 450° C. and at a pressure of between 3 Torr and 300 Torr.

6. The method of claim 1, wherein the nitrogen (N)-containing liquid precursor comprises ammonia (NH₃).

7. The method of claim 1, wherein the CVD soak process is performed at a temperature of between 300° C. to 450° C., for a time period of between 10 seconds and 30 seconds.

8. A method of forming and post-treating a metal silicide layer in a semiconductor structure, comprising:
performing a silicide deposition process, in which a metal silicide layer is deposited on a substrate;
performing a chemical vapor deposition (CVD) soak process in which the metal silicide layer is exposed to a silicon-containing precursor, forming a thin silicon (Si) layer over the metal silicide layer; and
performing a cap deposition process, in which a cap layer is deposited over the metal silicide layer.

9. The method of claim 8, wherein the metal silicide layer comprises molybdenum silicide.

10. The method of claim 8, wherein the metal silicide layer has a thickness of between 30 Å and 50 Å.

11. The method of claim 8, wherein the silicide deposition process comprises atomic layer deposition (ALD) or pseudo ALD using a deposition gas including a metal source.

12. The method of claim 11, wherein the silicide deposition process is performed at a temperature of between 240° C. and about 450° C. and at a pressure of between 3 Torr and 300 Torr.

13. The method of claim 8, wherein the silicon-containing precursor comprises silane (SiH₄) and disilane (Si₂H₆).

14. The method of claim 8, wherein the thin silicon (Si) layer has a thickness of between 5 Å and 8 Å.

15. The method of claim 8, wherein the CVD soak process is performed at a temperature of between 300° C. to 450° C., for a time period of between 10 seconds and 30 seconds.

16. A method of forming and post-treating a metal silicide layer in a semiconductor structure, comprising:
performing a silicide deposition process, in which a metal silicide layer is deposited on a substrate;
performing an anneal process in which the metal silicide layer is crystalized, forming a crystalized metal silicide layer over the metal silicide layer; and
performing a cap deposition process, in which a cap layer is deposited over the metal silicide layer.

17. The method of claim 16, wherein the metal silicide layer comprises molybdenum silicide and the crystalized metal silicide layer comprises molybdenum disilicide (MoSi₂).

18. The method of claim 16, wherein the metal silicide layer has a thickness of between 30 Å and 50 Å.

19. The method of claim 16, wherein the silicide deposition process comprises atomic layer deposition (ALD) or pseudo ALD using a deposition gas including a metal source.

20. The method of claim 16, wherein the anneal process is performed for between 5 second and 60 seconds, at a temperature of between 500 ° C. and 600 ° C., and at a pressure of between 5 Torr and 500 Torr.
